(19) United States
(12) Patent Application Publication
(10) Pub. No.: US 2007/0047308 A1
(43) Pub. Date: Mar. 1, 2007

(54) Memory controller, flash memory system and control method for flash memory

(76) Inventors: Takuma Mitsunaga, Tokyo (JP); Tsuyoshi Oyaizu, Tokyo (JP)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 11/513,630

(22) Filed: Aug. 31, 2006

(30) Foreign Application Priority Data
Aug. 31, 2005 (JP) 2005-252911

(51) Int. Cl. G11C 16/04

(52) U.S. Cl. 365/185.12

(57) ABSTRACT

A memory controller receives data to be stored in a flash memory by a host system in synchronism with a clock (external clock) to be a reference for an operation of the host system, and outputs the received data in synchronism with an internal clock of the memory controller. The memory controller receives data to be read from the flash memory by the host system in synchronism with the internal clock of the memory controller, and outputs the received data in synchronism with the external clock.

### RELATED APPLICATIONS

This application claims priority to Japanese Patent Application No. 2005-252911 filed on Aug. 31, 2005, which is incorporated herein by reference in its entirety.

### BACKGROUND OF THE INVENTION

1. Field of the Invention

The present invention relates to a memory controller, a flash memory system having the memory controller, and a control method for a flash memory.

2. Description of the Related Art

Recently, flash memories as non-volatile recording mediums are being actively developed and become popular as storage mediums for electronic devices, such as a digital camera.

A memory controller is used to control access to a flash memory by such an electronic device (hereinafter called “host system”). One of such memory controllers developed has a buffer (e.g., FIFO memory) which temporarily stores data to make data writing in a flash memory and data reading therefrom smoother (e.g., a memory controller disclosed in Unexamined Japanese Patent Application KOKAI Publication No. 2004-326574).

Such a buffer is often configured to be able to store multiple sectors of data (one sector being 512 bytes). A memory controller having the buffer generally performs a data input/output operation in synchronism with a clock in the memory controller (internal clock) both when receiving data from a host system and when passing data thereto.

To perform a data input/output operation in synchronism with the operational clock (external clock) of a host system, the buffer has only to be constituted by a so-called dual-port memory.

However, constituting every buffer having a memory capacity of storing multiple sectors of data by a dual-port memory raises problems, such as an increased circuit scale and increased consumption power.

### SUMMARY OF THE INVENTION

Accordingly, it is an object of the invention to provide a memory controller to which a host system can access in synchronism with the operational clock thereof, a flash memory system having the memory controller, and a control method for a flash memory.

A memory controller of the invention controls access to a flash memory of a host system which uses a flash memory as a storage medium, and comprises a first buffer circuit which receives data to be stored in the flash memory by the host system in synchronism with a first clock to be a reference for an operation of the host system, and outputs the received data in synchronism with a second clock to be a reference for an operation of the memory controller; and a second buffer circuit which receives data to be read from the flash memory by the host system in synchronism with the second clock, and outputs the received data in synchronism with the first clock.

Each of the first buffer circuit and the second buffer circuit may be configured to have an FIFO (First In First Out) memory.

The first buffer circuit may be configured to have a first counter which counts the first clock, and a second counter which counts the second clock, whereby the first buffer circuit writes data in a data storage area specified based on a count value of the first counter, and reads data from a data storage area specified based on a count value of the second counter.

The second buffer circuit may be configured to have a third counter which counts the first clock, and a fourth counter which counts the second clock, whereby the second buffer circuit reads data from a data storage area specified based on a count value of the third counter, and writes data in a data storage area specified based on a count value of the fourth counter.

The host system and the memory controller may be connected together by an external bus having an n-bit bus width, and the first buffer circuit may be configured to have a plurality of registers each having a memory capacity of n×m bits, and write data of n×m bits in the registers, n bits a time in m separate times.

The host system and the memory controller may be connected together by an external bus having an n-bit bus width, and the second buffer circuit may be configured to have a plurality of registers each having a memory capacity of n×m bits, and read data of n×m bits from the registers, n bits a time in m separate times.

The memory controller may further comprise a buffer which temporarily stores data to be stored in the flash memory or data read therefrom, whereby data output from the first buffer circuit is transferred to the flash memory via the buffer, and data read from the flash memory is transferred to the second buffer circuit via the buffer.

A memory capacity of each of the first buffer circuit and the second buffer circuit may be made smaller than a memory capacity of the buffer.

A flash memory system of the invention comprises a memory controller having any of the foregoing features, and a flash memory.

A flash memory control method of the invention controls access to a flash memory of a host system which uses a flash memory as a storage medium, and comprises a first buffering step of receiving data to be stored in the flash memory by the host system in synchronism with a first clock to be a reference for an operation of the host system, and outputting the received data in synchronism with a second clock to be a reference for an operation of the memory controller, and a second buffering step of receiving data to be read from the flash memory by the host system in synchronism with the second clock, and outputting the received data in synchronism with the first clock.

In each of the first buffering step and the second buffering step, data processing may be performed in an FIFO (First In First Out) fashion.

In the first buffering step, the first clock and the second clock may be counted, and data may be written in a data storage area specified based on a count value of the first clock, and data may be read from a data storage area specified based on a count value of the second clock.

In the second buffering step, the first clock and the second clock may be counted, and data may be read from a data storage area specified based on a count value of the first clock, and data may be written in a data storage area specified based on a count value of the second clock.

In the first buffering step, data of n×m bits may be written in the data storage area specified based on the count value of the first clock, n bits a time in m separate times.

In the second buffering step, data of n×m bits may be read from the data storage area specified based on the count value of the first clock, n bits a time in m separate times.

### BRIEF DESCRIPTION OF THE DRAWINGS

These objects and other objects and advantages of the present invention will become more apparent upon reading of the following detailed description and the accompanying drawings in which:

FIG. 1 is a block diagram schematically showing a flash memory system according to the present invention;

FIG. 2 is a diagram schematically showing the structure of an address space of a flash memory;

FIG. 3 is a block diagram showing the configuration of a host interface block;

FIG. 4 is a block diagram showing the configuration of a write FIFO;

FIG. 5 is a block diagram showing the configuration of a read FIFO;

FIGS. 6A to 6D are timing charts illustrating the operation of the write FIFO in a writing process; and

FIGS. 7A to 7D are timing charts illustrating the operation of the read FIFO in a reading process.

### DETAILED DESCRIPTION OF THE PREFERRED EMBODIMENT

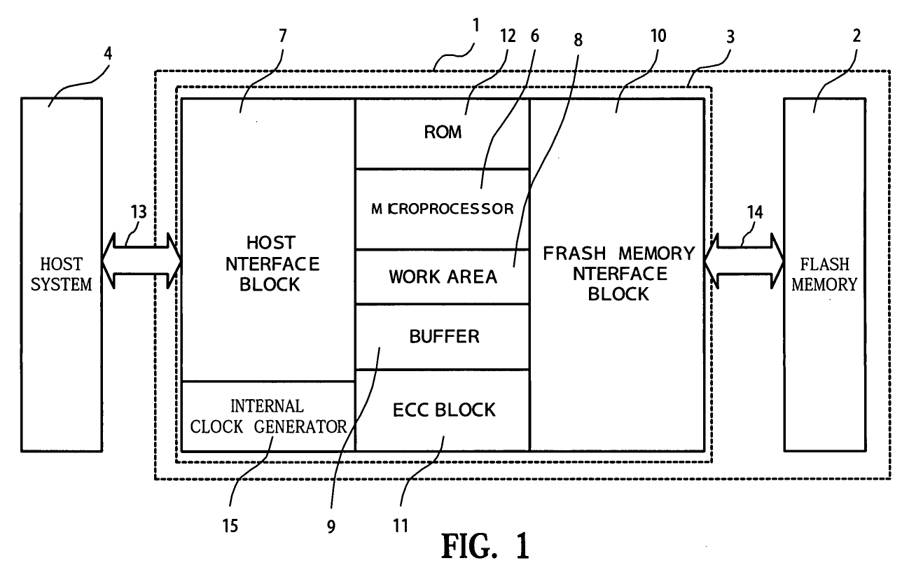

FIG. 1 is a block diagram schematically showing a flash memory system 1 according to the present invention. As shown in FIG. 1, the flash memory system 1 includes a flash memory 2 and a memory controller 3 which controls the flash memory 2.

The flash memory system 1 is connected to a host system 4 via an external bus 13. The external bus 13 in one embodiment of the invention has a 16-bit bus width. The host system 4 includes a CPU (Central Processing Unit) which controls the general operation of the host system 4, and a companion chip which exchanges information with the flash memory system 1. The host system 4 may be any of various information processing apparatuses (electronic devices) including a personal computer and a digital camera which process various kinds of information, such as text, voice and image information.

The host system 4 operates based on an external clock (BCLK) having a frequency different from that of an internal clock (UCLK) which is generated inside the memory controller 3 as an operational clock.

The flash memory 2, which is a non-volatile memory, includes registers and a memory cell array. The flash memory 2 performs data writing or data reading by executing data copy between a register and a memory cell.

The memory cell array has multiple groups of memory cells and word lines. Each memory cell group has a plurality of memory cells connected in series. A word line is for selecting a specific memory cell in a memory cell group. Data copy is performed between a memory cell selected through the word line and an associated register. That is, data copy from the associated register to the selected memory cell or data copy from the selected memory cell to the associated register is carried out.

Each of the memory cells constituting the memory cell array comprises an MOS transistor having two gates, respectively called a control gate and a floating gate. Data is written or erased by supplying charges (electrons) to the floating gate or draining charges (electrons) therefrom, respectively.

As the floating gate is surrounded by an insulator, supplied electrons are held over a long period of time. In supplying electrons to the floating gate, a voltage is applied in such a way that the floating gate has a high potential. In draining electrons from the floating gate, a voltage is applied in such a way that the floating gate has a low potential.

A write state is the state where electrons are supplied to the floating gate, and corresponds to a logic value “0”. An erase state is the state where electrons are drained from the floating gate, and corresponds to a logic value “1”.

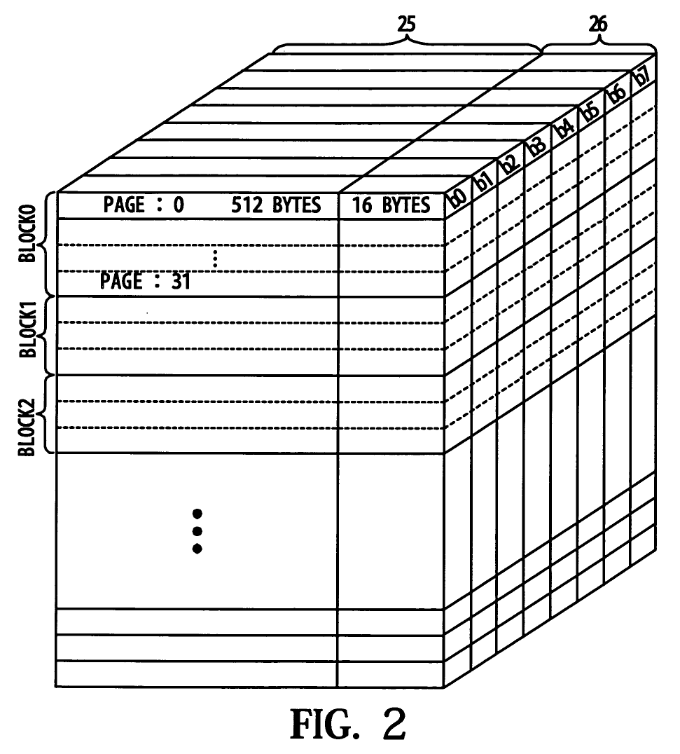

The address space of the flash memory 2 is illustrated in FIG. 2. The address space of the flash memory 2 is divided into “pages” and “blocks” and is managed accordingly.

A “page” is a process unit in a data reading operation and a data writing operation which are performed in the flash memory 2, and a “block” is a process unit in a data erasing operation which is performed in the flash memory 2.

In the flash memory shown in FIG. 2, one page includes one sector (512 bytes) of a user area 25 and a 16-byte redundant area 26. There is a flash memory in which one page includes four sectors of a user area and a 64-byte redundant area. The user area 25 stores user data to be sent from the host system 4.

The redundant area 26 is an area for recording additional data, such as an error correction code, a correlation logic block address, and a block status (flag).

The error correction code is data for detecting and correcting a possible error included in data stored in the user area 25.

The correlation logic block address indicates the address of a logic block associated with a block when effective data is stored in at least one user area 25 in that block.

The logic block address is the address of a block which is determined based on a host address given from the host system 4. The actual block address in the flash memory 2 is called “physical block address”.

When there is no effective data stored in any user area 25 in one block, there is no correlation logic block address stored in the redundant area 26 included in that block.

It is therefore possible to determine whether data in a block containing the redundant area 26 is erased by checking if a correlation logic block address is stored in the redundant area 26. When no correlation logic block address is stored in the redundant area 26, data has been erased from the associated block.

One block includes multiple pages. The flash memory 2 cannot overwrite data. Even in rewriting only data stored on one page, therefore, data stored in all the pages of the block having that page should be rewritten.

In other words, in normal data writing, data stored in all the pages of the block having a page to be rewritten is written in another block where data has been erased. In the data writing, data stored in any page where no data is to be changed is rewritten.

In rewriting data in this manner, data to be rewritten is written in a block different from the block where the data has been stored previously. Therefore, the correlation between the logic block address and the physical block address changes every time data is written in the flash memory 2.

This requires that the correlation between the logic block address and the physical block address should be managed. This correlation is normally managed according to an address conversion table. The address conversion table is created based on correlation logic block addresses stored in the redundant areas 26 of the individual pages. This dynamic address managing scheme is typical in a memory system using a flash memory.

The block status is a flag indicating whether a block is good or bad. A block where data cannot be written properly is discriminated as a defective block, and a block status indicative of a defective block is written in the associated redundant area 26.

The flash memory 2 receives data, address information, status information, an internal command, etc. from the memory controller 3, and performs processes, such as a data reading process, a data writing process, a block erasing process and a transfer process.

The internal command is a command from the memory controller 3 which instructs the flash memory 2 to execute a process, and the flash memory 2 operates according to the internal command from the memory controller 3. An external command, by way of contrast, is a command by which the host system 4 instructs the flash memory system 1 to execute a process.

As shown in FIG. 1, the memory controller 3 includes a microprocessor 6, a host interface block 7, a work area 8, a buffer 9, a flash memory interface block 10, an ECC (Error Correction Code) block 11, a ROM (Read Only Memory) 12, and an internal clock generator 15. The memory controller 3 constituted by those functional blocks is integrated on a single semiconductor chip. The functional blocks will be explained below.

The microprocessor 6 controls the general operation of the memory controller 3 according to a program stored in the ROM 12. For example, the microprocessor 6 reads from the work area 8 a command set which defines various processes or the like, and passes the command set to the flash memory interface block 10 to cause the flash memory interface block 10 to execute associated processes.

The internal clock generator 15 comprises a crystal oscillator or the like, and supplies the individual components of the memory controller 3 with an internal clock (UCLK) having a predetermined frequency, which is a operational reference for those components.

The host interface block 7 exchanges data, address information, status information, an external command, an external clock (BCLK), and so forth with the host system 4. Specifically, the flash memory system 1 and the host system 4 are connected together by the external bus 13 having a 16-bit bus width, and data or the like to be transferred to the flash memory system 1 from the host system 4 is fetched into the memory controller 3 (e.g., to the buffer 9) through the host interface block 7. Data or the like to be transferred to the host system 4 from the flash memory system 1 is temporarily stored in the memory controller 3 (e.g., the buffer 9), and transferred to the host system 4 through the host interface block 7. Data exchange between the host interface block 7 and the buffer 9 is executed via a data bus having a 64-bit bus width.

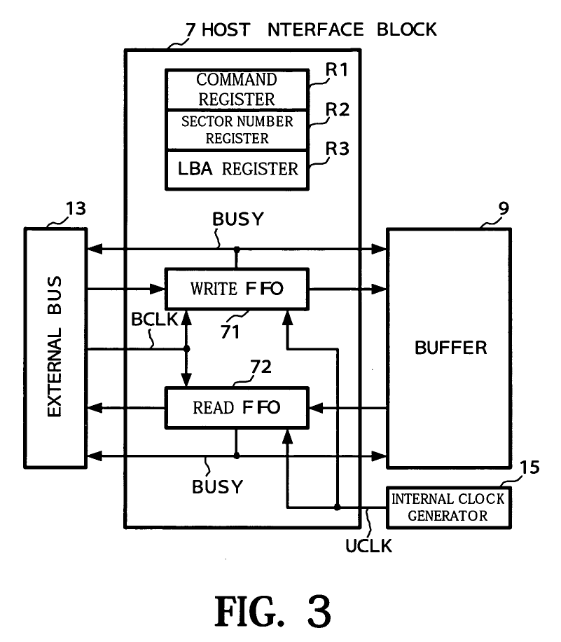

More specifically, as shown in FIG. 3, the host interface block 7 has a command register R1 which temporarily stores a host address and an external command sent from the host system 4, a sector number register R2 which stores the size of data to be written or read, and an LBA (Logical Block Addressing) register R3 which stores the logic address of data to be written or read. The host interface block 7 further has a write FIFO 71 (first buffer circuit) which temporarily stores data to be written, and a read FIFO 72 (second buffer circuit) which temporarily stores data to be read.

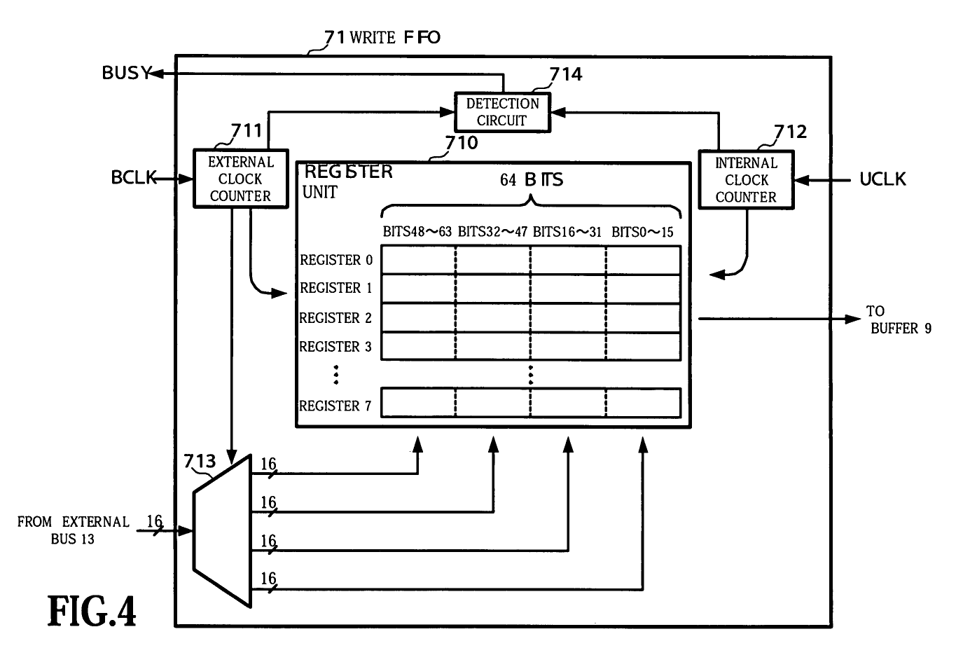

The write FIFO 71 comprises a register unit 710, an external clock counter 711, an internal clock counter 712, a demultiplexer 713, and a detection circuit 714, as shown in FIG. 4.

The register unit 710 has eight 64-bit registers (register 0 to register 7). That is, the register unit 710 can store ⅛ sector of data (64-byte data). Data to be stored in the register unit 710 is written in the register and bit sequence which are specified based on the count value of the external clock counter 711. At this time, data to be input via the external bus 13 is written in each register, 16 bits a time in four separate times. Data stored in the register unit 710 is read, 64 bits a time, from the register that is specified based on the count value of the internal clock counter 712, and is transferred to the buffer 9 via the data bus.

The external clock counter 711 is constituted by a 5-bit binary counter. The count value of the external clock counter 711 is used to specify a write register and a write bit sequence (any group of bits 0-15, bits 16-31, bits 32-47, and bits 48-63). More specifically, the write register is specified by the upper three bits (i.e., 0-7) of the count value, and the write bit sequence is specified by the lower two bits (i.e., 0-3).

The internal clock counter 712 is constituted by a binary counter of three bits (0-7). The count value of the internal clock counter 712 is used to specify a read register.

The demultiplexer 713 writes data to be transferred from the host system 4 via the external bus 13 into any bit sequence (any group of bits 0-15, bits 16-31, bits 3247 and bits 48-63) in each register by referring to the lower two bits of the count value of the external clock counter 711.

The detection circuit 714 monitors the upper three bits of the count value of the external clock counter 711 and the count value of the internal clock counter 712, and detects when one of the upper three bits of the count value of the external clock counter 711 and the count value of the internal clock counter 712 overtakes the other. When the upper three bits of the count value of the external clock counter 711 overtake the count value of the internal clock counter 712, the detection circuit 714 stops the operation of the external clock counter 711 and transfers a busy signal to the host system 4.

When the count value of the internal clock counter 712 overtakes the upper three bits of the count value of the external clock counter 711, on the other hand, the detection circuit 714 stops the operation of the internal clock counter 712 and transfers the busy signal to the buffer 9.

To match the progress speed of the process of writing data from the host system 4 to the register unit 710 with the progress speed of the process of reading data from the register unit 710 into the buffer 9, the internal clock may be adjusted (e.g., UCLK≈BCLK/4).

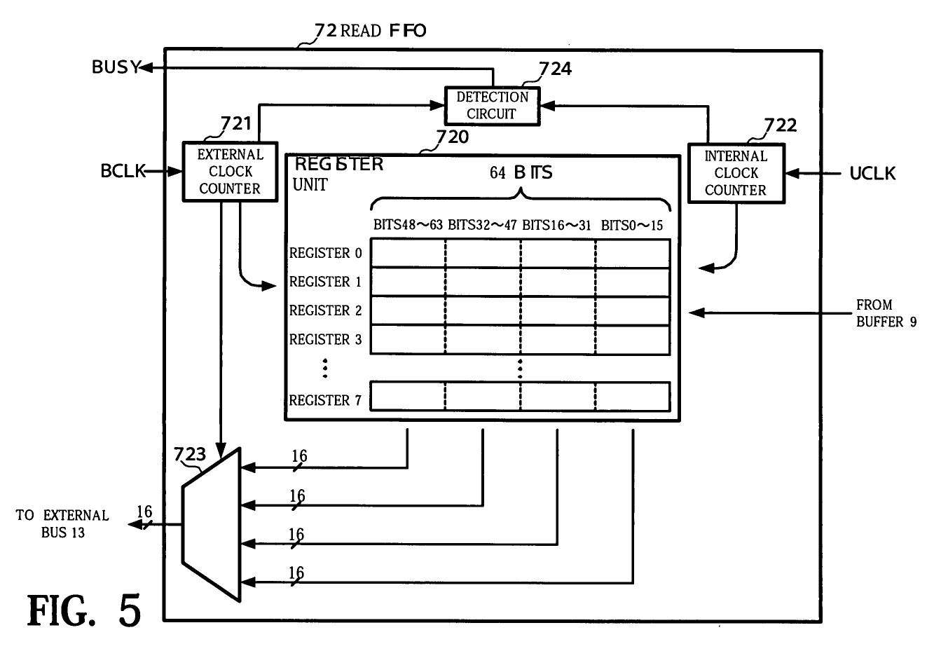

The read FIFO 72 comprises a register unit 720, an external clock counter 721, an internal clock counter 722, a multiplexer 723, and a detection circuit 724, as shown in FIG. 5.

The register unit 720 has eight 64-bit registers (register 0 to register 7). That is, the register unit 720 can store ⅛ sector of data (64-byte data). Data which is transferred from the buffer 9 via the data bus is written, 64 bits a time, in the register which is specified based on the count value of the internal clock counter 722. Data stored in the register unit 720 is read, 16 bits a time in four separate times, from the register and bit sequence which are specified based on the count value of the external clock counter 721, and is transferred to the host system 4 via the external bus 13.

The external clock counter 721 is constituted by a 5-bit binary counter. The count value of the external clock counter 721 is used to specify a read register and a read bit sequence (any group of bits 0-15, bits 16-31, bits 32-47, and bits 48-63). More specifically, the read register is specified by the upper three bits (i.e., 0-7) of the count value, and the read bit sequence is specified by the lower two bits (i.e., 0-3).

The internal clock counter 722 is constituted by a binary counter of three bits (0-7). The count value of the internal clock counter 722 is used to specify a write register.

The multiplexer 723 transfers data of any bit sequence (any group of bits 0-15, bits 16-31, bits 3247 and bits 48-63) in each register to the host system 4 via the external bus 13 by referring to the lower two bits of the count value of the external clock counter 721.

The detection circuit 724 monitors the upper three bits of the count value of the external clock counter 721 and the count value of the internal clock counter 722, and detects when one of the upper three bits of the count value of the external clock counter 721 and the count value of the internal clock counter 722 overtakes the other. When the upper three bits of the count value of the external clock counter 721 overtake the count value of the internal clock counter 722, the detection circuit 724 stops the operation of the external clock counter 721 and transfers a busy signal to the host system 4.

When the count value of the internal clock counter 722 overtakes the upper three bits of the count value of the external clock counter 721, on the other hand, the detection circuit 724 stops the operation of the internal clock counter 722 and transfers the busy signal to the buffer 9.

Returning to FIG. 1, the other functional blocks will be explained. The work area 8 is an area where data necessary for the control of the flash memory 2 is temporarily stored, and is constituted by multiple SRAM (Static Random Access Memory) cells.

The buffer 9 temporarily stores data read from the flash memory 2 and data to be written therein. Specifically, data read from the flash memory 2 is held in the buffer 9 until the host system 4 becomes ready to receive the data, and data to be written in the flash memory 2 is held in the buffer 9 until the flash memory 2 becomes a writable state.

The flash memory interface block 10 exchanges data, address information, status information, an internal command, etc. with the flash memory 2 via an internal bus 14. More specifically, the flash memory interface block 10 includes an address register, a command register, and a command processing block.

The address register stores the physical block address of an access destination. The physical block address is address information for designating a block in the flash memory 2 which is accessed in a sequence of control processes that is executed by the flash memory interface block 10.

The command register stores a sequence command constituting a command set. The command set includes a command to instruct a process in the memory controller 3 and a command to instruct transfer of an internal command, address information and the like to the flash memory 2.

The command processing block outputs an internal command, address information and the like for controlling the flash memory 2 according to the sequence command stored in the command register.

The flash memory interface block 10 causes the flash memory 2 to perform reading, writing, etc. by transferring an internal command, address information and or the like, output from the command processing block, to the flash memory 2.

The ECC block 11 generates an error correction code to be added to data to be written in the flash memory 2, and detects and corrects an error included in read data based on the error correction code added to the read data.

The ROM 12 is a non-volatile memory device to store a program which defines procedures of a process which is executed by the microprocessor 6. Specifically, the ROM 12 stores a program which defines process procedures, such as generation of the address conversion table.

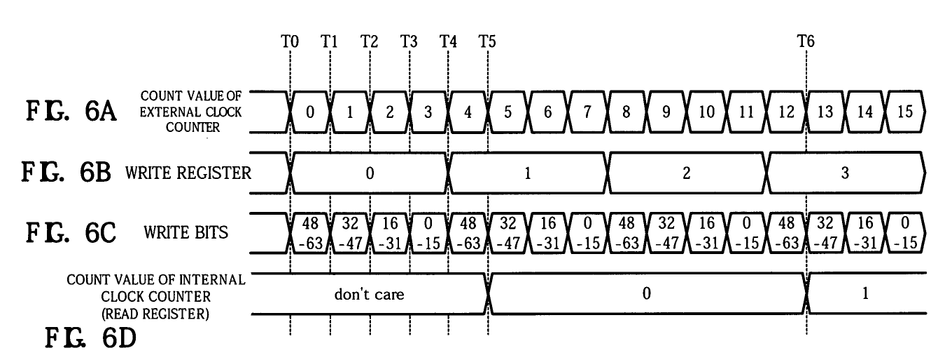

The operation of the write FIFO 71 at the time the host system 4 writes data into the flash memory 2 in the thus-constituted flash memory system 1 will be described referring to timing charts illustrated in FIGS. 6A to 6D.

In a writing process, the host system 4 sets the size of to-be-written data in the sector number register R2 of the host interface block 7, sets the logic address of to-be-written data in the LBA register R3, and then sets an external command instructing the writing process in the command register R1.

The memory controller 3 starts the writing process when the external command from the host system 4, which instructs the writing process, is set in the command register R1.

When the writing process starts, the external clock counter 711 of the write FIFO 71 is reset to have a count value of 0. Then, data to be written is sequentially transferred to the write FIFO 71 in synchronism with the external clock (BCLK).

The operation of writing data into the register unit 710 will be described specifically by referring to FIGS. 6A to 6C.

At time T0, the count value of the external clock counter 711 becomes 0, and data is written in the bit 48-63 in the register 0.

At time T1, the count value of the external clock counter 711 becomes 1, and data is written in the bit sequence 32-47 in the register 0.

At time T2, the count value of the external clock counter 711 becomes 2, and data is written in the bit sequence 16-31 in the register 0.

At time T3, the count value of the external clock counter 711 becomes 3, and data is written in the bit 0-15 in the register 0.

At time T4, the count value of the external clock counter 711 becomes 4, and data is written in the bit 48-63 in the register 1.

Thereafter, data is likewise written in the register unit 710 sequentially.

At time T5 where a predetermined time has passed after resetting of the external clock counter 711, the detection circuit 714 stops transferring the busy signal to the buffer 9. In synchronism with this action, the detection circuit 714 resets the internal clock counter 712 (i.e., the count value becomes 0). Thereafter, data is sequentially read and transferred to the buffer 9 in synchronism with the internal clock (UCLK).

The operation of reading data from the register unit 710 will be described specifically by referring to FIG. 6D.

At time T5, the count value of the internal clock counter 712 becomes 0, and data in the register 0 is transferred to the buffer 9.

At time T6, the count value of the internal clock counter 712 becomes 1, and data in the register 1 is transferred to the buffer 9.

Thereafter, data is likewise sequentially transferred to the buffer 9.

When the write register overtakes the read register (i.e., when the upper three bits of the count value of the external clock counter 711 overtake the count value of the internal clock counter 712), the detection circuit 714 stops the operation of the external clock counter 711 and transfers the busy signal to the host system 4 to temporarily stop data transfer.

When the read register overtakes the write register, on the other hand, the detection circuit 714 stops the operation of the internal clock counter 712 and transfers the busy signal to the buffer 9 to temporarily stop data reading therefrom.

When a predetermined time passes after the write register overtakes the read register, the detection circuit 714 resumes the operation of the external clock counter 711, and stops transferring the busy signal to the host system 4. As a result, data writing to the register is resumed.

Data read into the buffer 9 from the write FIFO 71 is held in the buffer 9 until the flash memory 2 becomes a writable state. When the flash memory 2 becomes a writable state, the read data is written on a desired page in the flash memory 2 via the flash memory interface block 10 and the internal bus 14.

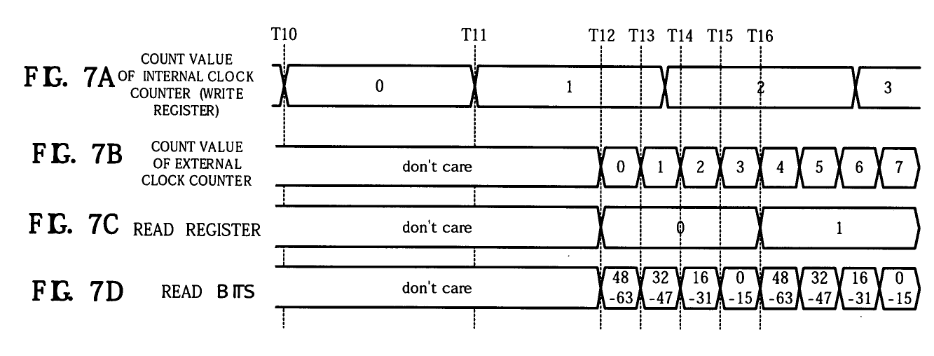

The operation of the read FIFO 72 at the time the host system 4 reads data from the flash memory 2 in the flash memory system 1 will be described referring to timing charts illustrated in FIGS. 7A to 7D.

The host system 4 sets the size of data to be read in the sector number register R2 of the host interface block 7, sets the logic address of data to be read in the LBA register R3, and then sets an external command instructing the reading process in the command register R1.

The memory controller 3 starts the reading process when the external command instructing the reading process is set in the command register R1.

In the reading process, the microprocessor 6 converts a logic address to a physical address. Data stored at the physical address in the flash memory 2 is read by the flash memory interface block 10, and is stored in the buffer 9 via the internal bus 14. The data stored in the buffer 9 is transferred to the host system 4 from the buffer 9 by the operation of the read FIFO 72 that will be described below.

First, the internal clock counter 722 of the read FIFO 72 is reset to have a count value of 0. Then, data stored in the buffer 9 is sequentially transferred to the read FIFO 72 in synchronism with the internal clock (UCLK).

The operation of writing data into the register unit 720 will be described specifically by referring to FIG. 7A.

At time T10, the count value of the internal clock counter 722 becomes 0, and data from the buffer 9 is written in the register 0.

At time T11, the count value of the internal clock counter 722 becomes 1, and data from the buffer 9 is written in the register 1.

Thereafter, data stored in the buffer 9 is likewise written in the register unit 720 sequentially.

At time T12 where a predetermined time has passed after resetting of the internal clock counter 722, the detection circuit 724 stops transferring the busy signal to the host system 4. In synchronism with this action, the detection circuit 724 resets the external clock counter 721 (i.e., the count value becomes 0). Thereafter, data is sequentially read and transferred to the host system 4 in synchronism with the external clock (BCLK).

The operation of transferring data to the host system 4 will be described specifically by referring to FIGS. 7B to 7D.

At time T12, the count value of the external clock counter 721 becomes 0, and data in the bit 48-63 in the register 0 is transferred to the host system 4.

At time T13, the count value of the external clock counter 721 becomes 1, and data in the bit 32-47 in the register 0 is transferred to the host system 4.

At time T14, the count value of the external clock counter 721 becomes 2, and data in the bit 16-31 in the register 0 is transferred to the host system 4.

At time T15, the count value of the external clock counter 721 becomes 3, and data in the bit 0-15 in the register 0 is transferred to the host system 4.

At time T16, the count value of the external clock counter 721 becomes 4, and data in the bit 48-63 in the register 1 is transferred to the host system 4.

Thereafter, data is likewise transferred to the host system 4 sequentially.

When the read register overtakes the write register (i.e., when the upper three bits of the count value of the external clock counter 721 overtake the count value of the internal clock counter 722), the detection circuit 724 stops the operation of the external clock counter 721 and transfers the busy signal to the host system 4 to temporarily stop data reading.

When the write register overtakes the read register, on the other hand, the detection circuit 724 stops the operation of the internal clock counter 722 and transfers the busy signal to the buffer 9 to temporarily stop data transfer.

When a predetermined time passes after the read register overtakes the write register, the detection circuit 724 resumes the operation of the external clock counter 721, and stops transferring the busy signal to the host system 4. As a result, data reading from the register is resumed.

To prevent the read register from overtaking the write register during transfer of one sector of data to the host system 4 from the buffer 9, the size of data which should have been stored in the read FIFO 72 at the beginning should be increased and the timing of stopping the transfer of the busy signal to the host system 4 should be delayed. It is preferable that the memory capacity of the read FIFO 72 should be set in consideration of the size of the data that should have been stored at the beginning.

As apparent from the foregoing description, the flash memory system 1 of the embodiment can execute a process of writing data from the host system 4 into the flash memory 2 (writing process) and a process of transferring data stored in the flash memory 2 to the host system 4 (reading process) in synchronism with the external clock (BCLK) which is the operational clock of the host system 4.

In the flash memory system 1 of the embodiment, the write FIFO 71 and the read FIFO 72 respectively have the demultiplexer 713 and the multiplexer 723. This can achieve smooth data transfer and reception even when the bit width of the external bus 13, which connects the host system 4 to the flash memory system 1, differs from the bit width of the data bus in the memory controller 3.

Although the foregoing description of the embodiment has been given of the case where the bit width of the external bus 13 (16 bits) differs from the bit width of the data bus in the memory controller 3 (64 bits), the external bus 13 and the data bus in the memory controller 3 may have the same bit width.

Although the register unit (710, 720) of each of the write FIFO 71 and the read FIFO 72 comprises eight registers in the embodiment, the number of the registers constituting the register unit of each FIFO is not limited, and may be greater or less than eight. The number of the registers provided in the write FIFO 71 may differ from the number of the registers provided in the read FIFO 72.

While each of the registers provided in the write FIFO 71 and the read FIFO 72 has a bit width of 64 bits, the bit width of the registers is not limited to 64 bits, but may be greater or less than 64 bits.

The memory capacities of the write FIFO 71 and the read FIFO 72 are not particularly limited; for example, even with a memory capacity smaller than the size of one sector, data transfer between the host system 4 and the buffer 9 can be executed smoothly.

The foregoing description of the embodiment has been given of the case where fetching data from the host system 4 to the write FIFO 71 and outputting of data from the read FIFO 72 to the host system 4 are always executed in synchronism with the external clock (BCLK). However, fetching data from the host system 4 to the write FIFO 71 and outputting of data from the read FIFO 72 to the host system 4 may be executed in synchronism with the external clock (BCLK) or the internal clock (UCLK) whichever is selected.

Making the external clock (BCLK) and the internal clock (UCLK) selectable can ensure access to the flash memory 2 even with a configuration which does not allow the host system 4 to supply the external clock (BCLK) to the memory controller 3.

Various embodiments and changes may be made thereunto without departing from the broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

What is claimed is:

1. A memory controller that controls access to a flash memory of a host system which uses a flash memory as a storage medium, comprising:
a first buffer circuit which receives data to be stored in said flash memory by said host system in synchronism with a first clock to be a reference for an operation of said host system, and outputs said received data in synchronism with a second clock to be a reference for an operation of said memory controller; and
a second buffer circuit which receives data to be read from said flash memory by said host system in synchronism with said second clock, and outputs said received data in synchronism with said first clock.

2. The memory controller according to claim 1, wherein each of said first buffer circuit and said second buffer circuit has an FIFO (First In First Out) memory.

3. The memory controller according to claim 1, wherein said first buffer circuit has a first counter which counts said first clock, and a second counter which counts said second clock, whereby said first buffer circuit writes data in a data storage area specified based on a count value of said first counter, and reads data from a data storage area specified based on a count value of said second counter.

4. The memory controller according to claim 1, wherein said second buffer circuit has a third counter which counts said first clock, and a fourth counter which counts said second clock, whereby said second buffer circuit reads data from a data storage area specified based on a count value of said third counter, and writes data in a data storage area specified based on a count value of said fourth counter.

5. The memory controller according to claim 1, wherein said host system and said memory controller are connected together by an external bus having an n-bit bus width, and said first buffer circuit has a plurality of registers each having a memory capacity of n×m bits, and writes data of n×m bits in said registers, n bits a time in m separate times.

6. The memory controller according to claim 1, wherein said host system and said memory controller are connected together by an external bus having an n-bit bus width, and said second buffer circuit has a plurality of registers each having a memory capacity of n×m bits, and reads data of n×m bits from said registers, n bits a time in m separate times.

7. The memory controller according to claim 1, further comprising a buffer which temporarily stores data to be stored in said flash memory or data read therefrom, whereby data output from said first buffer circuit is transferred to said flash memory via said buffer, and data read from said flash memory is transferred to said second buffer circuit via said buffer.

8. The memory controller according to claim 7, wherein a memory capacity of each of said first buffer circuit and said second buffer circuit is smaller than a memory capacity of said buffer.

9. A flash memory system comprising a memory controller as recited in claim 1, and a flash memory.

10. A flash memory control method that controls access to a flash memory of a host system which uses a flash memory as a storage medium, comprising:
a first buffering step of receiving data to be stored in said flash memory by said host system in synchronism with a first clock to be a reference for an operation of said host system, and outputting said received data in synchronism with a second clock to be a reference for an operation of said memory controller; and
a second buffering step of receiving data to be read from said flash memory by said host system in synchronism with said second clock, and outputting said received data in synchronism with said first clock.

11. The flash memory control method according to claim 10, wherein in each of said first buffering step and said second buffering step, data processing is performed in an FIFO (First In First Out) fashion.

12. The flash memory control method according to claim 10, wherein in said first buffering step, said first clock and said second clock are counted, and data is written in a data storage area specified based on a count value of said first clock, and data is read from a data storage area specified based on a count value of said second clock.

13. The flash memory control method according to claim 10, wherein in said second buffering step, said first clock and said second clock are counted, and data is read from a data storage area specified based on a count value of said first clock, and data is written in a data storage area specified based on a count value of said second clock.

14. The flash memory control method according to claim 12, wherein in said first buffering step, data of n×m bits are written in said data storage area specified based on said count value of said first clock, n bits a time in m separate times.

15. The flash memory control method according to claim 13, wherein in said second buffering step, data of n×m bits are read from said data storage area specified based on said count value of said first clock, n bits a time in m separate times.
